(19) United States
(12) Patent Application Publication
(10) Pub. No.: US 2025/0201601 A1
(43) Pub. Date: Jun. 19, 2025

(54) PLASMA PROCESSING APPARATUS AND TEMPERATURE MEASUREMENT METHOD

(71) Applicant: Tokyo Electron Limited, Tokyo (JP)

(72) Inventors: Kazuhito YAMADA, Miyagi (JP); Shinya TAMONOKI, Miyagi (JP)

(73) Assignee: Tokyo Electron Limited, Tokyo (JP)

(21) Appl. No.: 19/064,041

(22) Filed: Feb. 26, 2025

Related U.S. Application Data
(63) Continuation of application No. PCT/JP2023/029549, filed on Aug. 16, 2023.

(30) Foreign Application Priority Data
Aug. 29, 2022 (JP) 2022-135651

(51) Int. Cl. H01L 21/67; G01K 3/10; H01J 37/32; H01L 21/683

(52) U.S. Cl. CPC H01L 21/67248; G01K 3/10; H01J 37/32724; H01L 21/6833; H01J 2237/2007; H01J 2237/24585

(57) ABSTRACT

A plasma processing apparatus includes a plasma processing chamber, a base disposed in the plasma processing chamber, an electrostatic chuck disposed on the base, a first heater electrode layer disposed in the electrostatic chuck, a second heater electrode layer disposed in the electrostatic chuck at a position different from the first heater electrode layer in a plan view, a first temperature sensor configured to measure a temperature of the first heater electrode layer, a second temperature sensor configured to measure a temperature of the second heater electrode layer, a signal line electrically connected to the first temperature sensor and the second temperature sensor, a ground (GND) line electrically connected to the first temperature sensor and the second temperature sensor, and a signal detector electrically connected to the signal line and the GND line.

### CROSS-REFERENCE TO RELATED APPLICATIONS

This application is a bypass continuation application of international application No. PCT/JP2023/029549 having an international filing date of Aug. 16, 2023 and designating the United States, the international application being based upon and claiming the benefit of priority from Japanese Patent Application No. 2022-135651, filed on Aug. 29, 2022, the entire contents of which are incorporated herein by reference.

### TECHNICAL FIELD

The present disclosure relates to a plasma processing apparatus and a temperature measurement method.

### BACKGROUND

Patent Document 1 discloses a technology in which a placement surface of a stage on which a substrate is placed is divided into a plurality of zones and a heater is provided in each of the plurality of divided zones to control a temperature of each zone in the placement surface.

### PRIOR ART DOCUMENTS

### Patent Documents

Patent Document 1: U.S. Patent Application Publication No. 2017/0167790
Patent Document 2: Japanese Laid-Open Patent Publication No. 2020-009795

### SUMMARY

According to one aspect of the present disclosure, a plasma processing apparatus includes a plasma processing chamber, a base disposed in the plasma processing chamber, an electrostatic chuck disposed on the base, a first heater electrode layer disposed in the electrostatic chuck, a second heater electrode layer disposed in the electrostatic chuck at a position different from the first heater electrode layer in a plan view, a first temperature sensor configured to measure a temperature of the first heater electrode layer, a second temperature sensor configured to measure a temperature of the second heater electrode layer, a signal line electrically connected to the first temperature sensor and the second temperature sensor, a ground (GND) line electrically connected to the first temperature sensor and the second temperature sensor, and a signal detector electrically connected to the signal line and the GND line.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a configuration of a capacitively coupled plasma processing apparatus according to a first embodiment.

FIG. 2 is a diagram illustrating an example of a configuration of a substrate support according to the first embodiment.

FIG. 3 is a diagram illustrating an example of the configuration of the substrate support according to the first embodiment.

FIG. 4 is a diagram schematically illustrating the configuration of the substrate support according to the first embodiment.

FIG. 5 is a diagram illustrating an example of a flow of detecting a temperature by each temperature sensor according to the first embodiment.

FIG. 6 is a diagram illustrating an example of a fluctuation in voltage of a common line when switching switches according to the first embodiment.

FIG. 7 is a diagram illustrating an example of a configuration of a substrate support according to a Comparative Example.

FIG. 8 is a diagram illustrating an example of a processing sequence of a temperature measurement method according to the first embodiment.

FIG. 9 is a diagram illustrating a schematic configuration of a substrate support according to a second embodiment.

FIG. 10 is a diagram illustrating an example of a flow of detecting a temperature by each temperature sensor according to the second embodiment.

FIG. 11 is a diagram illustrating another example of the schematic configuration of the substrate support according to the second embodiment.

FIG. 12 is a diagram illustrating an example of a configuration of a substrate support according to another embodiment.

### DETAILED DESCRIPTION

Hereinafter, embodiments of a plasma processing apparatus and a temperature measurement method disclosed herein will be described in detail with reference to the drawings. The plasma processing apparatus and the temperature measurement method disclosed herein are not limited by these embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In plasma processes, such as a plasma etching process and a film formation process, processing conditions change according to a temperature of each zone of a substrate. For this reason, a plasma processing apparatus uses a stage that has a placement surface divided into a plurality of zones and is capable of controlling a temperature of each zone. In the stage, a heater and a temperature sensor are provided for each zone. In the plasma processing apparatus, each temperature sensor is connected to a control board to measure a temperature, and a temperature of the heater is controlled according to the temperature measured by the temperature sensor in each zone.

The plasma processing apparatus finely controls the temperature of the substrate in each zone. As a result, the number of zones in the stage tends to increase. As the number of zones increases, the number of temperature sensors also increases, so that the number of components required to connect the control board to each temperature sensor increases.

Therefore, a technique capable of suppressing an increase in the number of components used for temperature measurement is needed.

### First Embodiment

### <Configuration of Apparatus>

An example of the plasma processing apparatus of the present disclosure will now be described. In the following embodiments, a case in which the plasma processing apparatus of the present disclosure is used as a plasma processing system of a system configuration will be described by way of example.

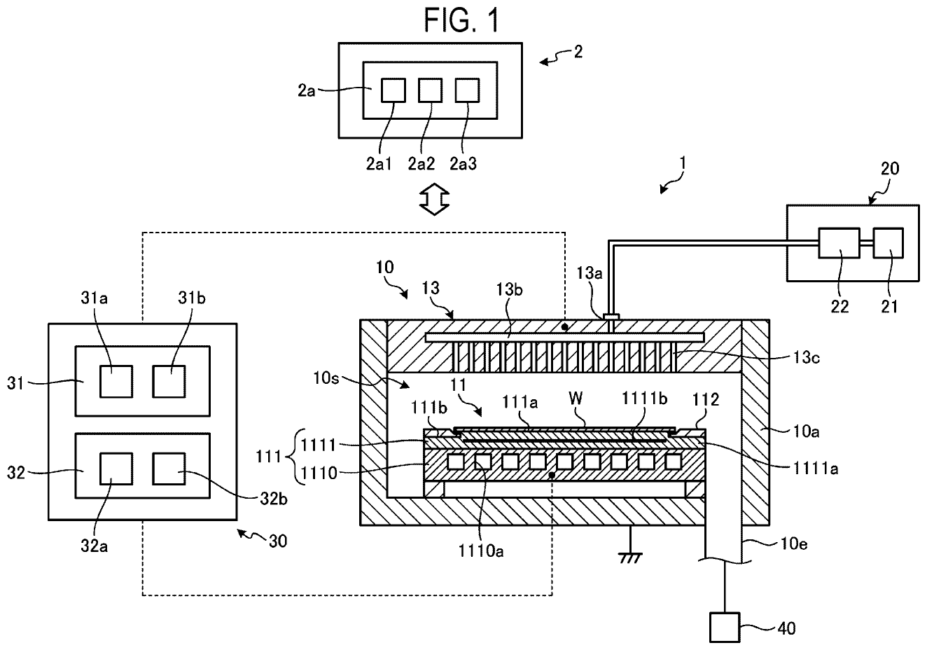

Hereinafter, an example of a configuration of the plasma processing system will be described. FIG. 1 is a diagram illustrating an example of a configuration of a capacitively coupled plasma processing apparatus according to a first embodiment.

The plasma processing system includes a capacitively coupled plasma processing apparatus 1 and a controller 2. The capacitively coupled plasma processing apparatus 1 includes a plasma processing chamber 10, a gas supplier 20, a power supply 30, and an exhaust system 40. The plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 includes at least one gas supply port for supplying at least one processing gas to the plasma processing space 10s therethrough and at least one gas discharge port for discharging the gas from the plasma processing space therethrough. The plasma processing chamber 10 is grounded. The showerhead 13 and the substrate support 11 are electrically insulated from a housing of the plasma processing chamber 10. The substrate support 11 corresponds to the stage of the present disclosure.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one radio frequency (RF) and/or direct current (DC) electrode coupled to an RF power supply 31 and/or a DC power supply 32 described later may be disposed in the ceramic member 1111a. In this case, at least one RF/DC electrode functions as the lower electrode. In a case in which a bias RF signal and/or a DC signal described later is supplied to the at least one RF/DC electrode, the RF/DC electrode is also referred to as a bias electrode. The conductive member of the base 1110 and the at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of the insulating material.

The substrate support 11 may include a temperature control module configured to control at least one of the electrostatic chuck 1111, the ring assembly 112, or the substrate to a target temperature. The temperature control module may include a heater, a heat transfer medium, a flow passage 1110a, or a combination thereof. A heat transfer fluid such as brine or gas flows through the flow passage 1110a. In one embodiment, the flow passage 1110a is formed inside the base 1110, and one or more heaters are disposed in the ceramic member 1111a of the electrostatic chuck 1111. The substrate support 11 may include a heat-transfer-gas supplier configured to supply a heat transfer gas to a gap between a back surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s via the plurality of gas introduction ports 13c. The shower head 13 includes at least one upper electrode. In addition to the shower head 13, the gas introducer may include one or more side gas injectors (SGIs) installed in one or more openings formed in the sidewall 10a.

The gas supplier 20 may include at least one gas source 21 and at least one flow rate controller 22. In one embodiment, the gas supplier 20 is configured to supply at least one processing gas to the shower head 13 from each corresponding gas source 21 via each corresponding flow controller 22. Each flow controller 22 may include, for example, a mass flow controller or a pressure-controlled flow rate controller. In addition, the gas supplier 20 may include one or more flow rate modulation devices that modulate or pulse a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. Thus, plasma is formed from the at least one processing gas supplied to the plasma processing space 10s. Therefore, the RF power supply 31 may function as at least a part of a plasma generator configured to generate plasma from the one or more processing gases in the plasma processing chamber 10. Further, by supplying a bias RF signal to the at least one lower electrode, a bias potential is generated on the substrate W and ion components in the formed plasma are drawn into the substrate W.

In one embodiment, the RF power supply 31 includes a first RF generator 31a and a second RF generator 31b. The first RF generator 31a is coupled to the at least one lower electrode and/or the at least one upper electrode via at least one impedance matching circuit and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The one or more source RF signals thus generated are supplied to the at least one lower electrode and/or the at least one upper electrode.

The second RF generator 31b is coupled to the at least one lower electrode via the at least one impedance matching circuit and is configured to generate a bias RF signal (bias RF power). A frequency of the bias RF signal may be the same as or different from the frequency of the source RF signal. In one embodiment, the bias RF signal has a frequency lower than that of the source RF signal. In one embodiment, the bias RF signal has a frequency in a range of 100 kHz to 60 MHz. In one embodiment, the second RF generator 31b may be configured to generate a plurality of bias RF signals having different frequencies. The one or more bias RF signals thus generated are supplied to the at least one lower electrode. In various embodiments, at least one of the source RF signal or the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to the at least one lower electrode and is configured to generate a first DC signal. The first bias DC signal thus generated is applied to the at least one lower electrode. In one embodiment, the second DC generator 32b is connected to the at least one upper electrode and is configured to generate a second DC signal. The second DC signal thus generated is applied to the at least one upper electrode.

In various embodiments, at least one of the first DC signal or the second DC signal may be pulsed. In this case, a sequence of voltage pulses is applied to the at least one lower electrode and/or the at least one upper electrode. The voltage pulses may have pulse waveforms that are rectangular, trapezoidal, triangular, or combinations thereof. In one embodiment, a waveform generator for generating the sequence of the voltage pulses from the DC signal is connected between the first DC generator 32a and the at least one lower electrode. Accordingly, the first DC generator 32a and the waveform generator constitute a voltage pulse generator. When the second DC generator 32b and the waveform generator constitute the voltage pulse generator, the voltage pulse generator is connected to the at least one upper electrode. The voltage pulses may have positive polarity or negative polarity. Further, the sequence of the voltage pulses may include one or more positive polarity voltage pulses or one or more negative polarity voltage pulses in one cycle. The first DC generator 32a and the second DC generator 32b may be provided in addition to the RF power supply 31, and the first DC generator 32a may be provided instead of the second RF generator 31b.

The exhaust system 40 may be connected to, for example, a gas discharge port 10e provided at the bottom of the plasma processing chamber 10. The exhaust system 40 may include a pressure regulating valve and a vacuum pump. An internal pressure of the plasma processing space 10s is regulated by the pressure regulating valve. The vacuum pump may include a turbo-molecular pump, a dry pump, or a combination thereof.

The controller 2 processes a computer-executable instruction that causes the plasma processing apparatus 1 to execute various processes described in the present disclosure. The controller 2 may be configured to control individual constituent elements of the plasma processing apparatus 1 to execute various processes described herein. In one embodiment, a part or all of the controller 2 may be included in the plasma processing apparatus 1. The controller 2 may include a processor 2a1, a storage 2a2, and a communication interface 2a3. The controller 2 is implemented with, for example, a computer 2a. The processor 2al may be configured to perform various control operations by reading a program from the storage 2a2 and executing the read program. This program may be stored in the storage 2a2 in advance or may be acquired via a medium when necessary. The acquired program is stored in the storage 2a2 and is read from the storage 2a2 by the processor 2al and executed. The medium may be various non-transitory storage media readable by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

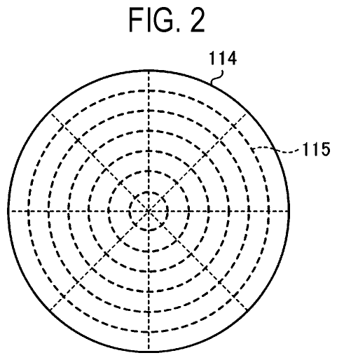

Next, a configuration of the substrate support 11 according to the first embodiment will be described. FIG. 2 is a diagram illustrating an example of the configuration of the substrate support 11 according to the first embodiment. FIG. 2 illustrates a plan view of a placement surface 114 of the electrostatic chuck 1111 on which the substrate W is placed. The placement surface 114 corresponds to the central region 111a in FIG. 1.

In the example of FIG. 2, the placement surface 114 is a substantially circular area in a plan view. The placement surface 114 is formed to have a diameter substantially the same as or slightly smaller than a diameter of the substrate W.

The substrate support 11 is configured to be capable of controlling the temperature of each zone 115 obtained by dividing the placement surface 114 of the electrostatic chuck 1111. For example, the electrostatic chuck 1111 is divided into a plurality of zones 115, and a heater is embedded in each of the plurality of zones 115. The placement surface 114 includes the heater provided in each zone 115 of the electrostatic chuck 1111 to control the temperature of each zone 115. A method of dividing the placement surface 114 to form the zones 115, which is illustrated in FIG. 2, is merely an example, and the present disclosure is not limited thereto. For example, the placement surface 114 may be divided into the zones 115 having a circular zone at the center thereof. Further, the placement surface 114 may be divided into the zones 115 of grid shapes. Further, the placement surface 114 may be divided into zones 115 of another shape. For example, the placement surface 114 may be divided into the zones 115 of an arc shape with a smaller angle width and a narrower radial width toward an outer periphery of the placement surface 114.

The substrate support 11 is configured to be capable of measuring the temperature of each zone 115 of the placement surface 114. For example, the substrate support 11 is provided with a temperature sensor in each zone 115 to measure the temperature of each zone 115.

In the embodiment, the case in which the placement surface 114 (the central region 111a) of the electrostatic chuck 1111 on which the substrate W is placed is divided into the zones 115 and the temperature of each zone 115 may be controlled has been described. However, the present disclosure is not limited thereto. As an example, heaters and temperature sensors may be provided in the annular region 111b in which the ring assembly 112 is placed to control the temperature of the annular region 111b. For example, the central region 111a and the annular region 111b as the placement surface 114 may be divided into the zones 115.

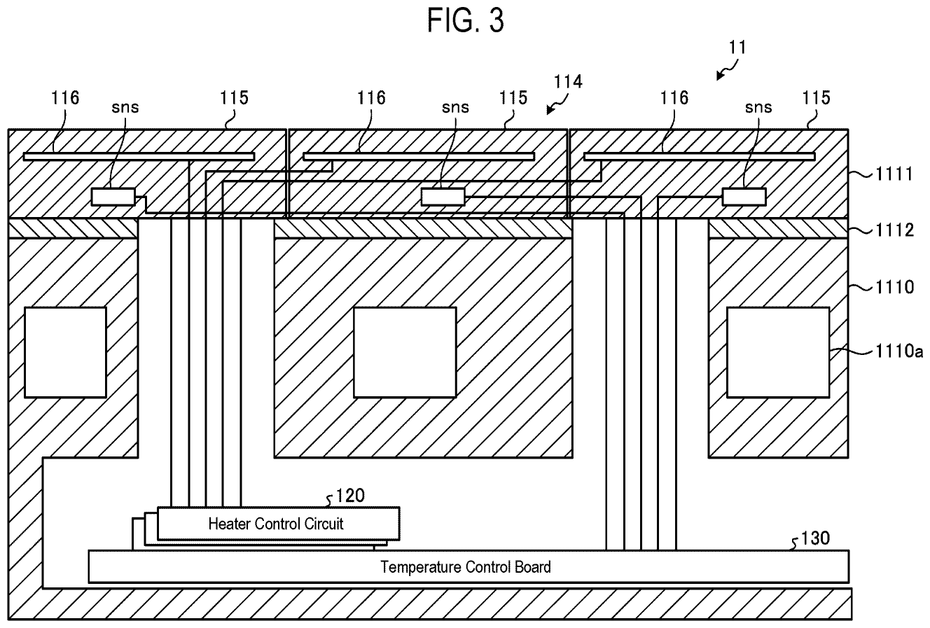

FIG. 3 is a diagram illustrating an example of a schematic configuration of the substrate support 11 according to the first embodiment. In FIG. 3, a cross-sectional view of the substrate support 11 is illustrated.

The substrate support 11 is configured to be capable of supporting the substrate W. For example, the main body 111 of the substrate support 11 includes the electrostatic chuck 1111 disposed on the base 1110. The electrostatic chuck 1111 is bonded to the base 1110 by a bonding layer 1112. An upper surface of the electrostatic chuck 1111 corresponds to the placement surface 114.

The base 1110 includes a conductive member. For example, the base 1110 is formed of a conductive metal such as aluminum.

The electrostatic chuck 1111 includes an insulating layer such as ceramic and an electrode of a film shape provided inside the insulating layer. The electrostatic chuck 1111 generates electrostatic attractive force by applying a DC voltage from a power supply (not illustrated) to the electrode provided therein, thereby attracting and holding the substrate W.

A flow path 1110a through which a heat transfer fluid flows is formed in an interior of the base 1110, which is located below the placement surface 114. Further, the electrostatic chuck 1111 is provided with heaters 116 for the zones 115. Each heater 116 is an electrode layer provided inside the electrostatic chuck 1111. The heaters 116 correspond to a first heater electrode layer and a second heater electrode of the present disclosure. The substrate support 11 causes the heat transfer fluid whose temperature is controlled to flow through the flow path 1110a, thereby entirely controlling the temperatures of the zones 115 and individually controlling the temperature of each zone 115 by heating each zone 115 with one heater 116.

The electrostatic chuck 1111 is provided with a temperature sensor sns for each zone 115. The temperature sensor sns may be provided inside the base 1110 or the bonding layer 1112. A plurality of heater control circuits 120 and a temperature control board 130 may be provided below the base 1110. Each heater 116 is connected to any one of the heater control circuits 120. Each heater control circuit 120 is configured to be capable of controlling the temperature of the heater 116 by controlling power to be supplied to the heater 116.

Each temperature sensor sns is connected to the temperature control board 130. The temperature control board 130 measures the temperature of each zone 115 using each temperature sensor sns.

Each heater control circuit 120 and the temperature control board 130 are connected to the controller 2. The temperature control board 130 outputs measured temperature data of each zone 115 to the controller 2. Under the control of the controller 2, the heater control circuit 120 supplies individually-adjusted power with respect to each heater 116.

Herein, when measuring the temperature of each zone 115 using the temperature sensor sns provided for each of the zones 115, which are obtained by dividing the placement surface 114 of the substrate support 11 into a plurality of regions, the number of components, such as detection circuits for detecting the temperature of each temperature sensor sns or connectors necessary for connection to each temperature sensor sns, increases. Since the plasma processing apparatus 1 needs to finely control the temperature of the substrate W for each zone, the number of zones 115 of the placement surface 114 of the substrate support 11 tends to increase. However, the temperature control board 130 requires more components for connection to each temperature sensor sns as the number of zones 115 increases. A size of the temperature control board 130 is restricted. Thus, a space for installing the components is also restricted, which makes it difficult to embed the components required for the connection.

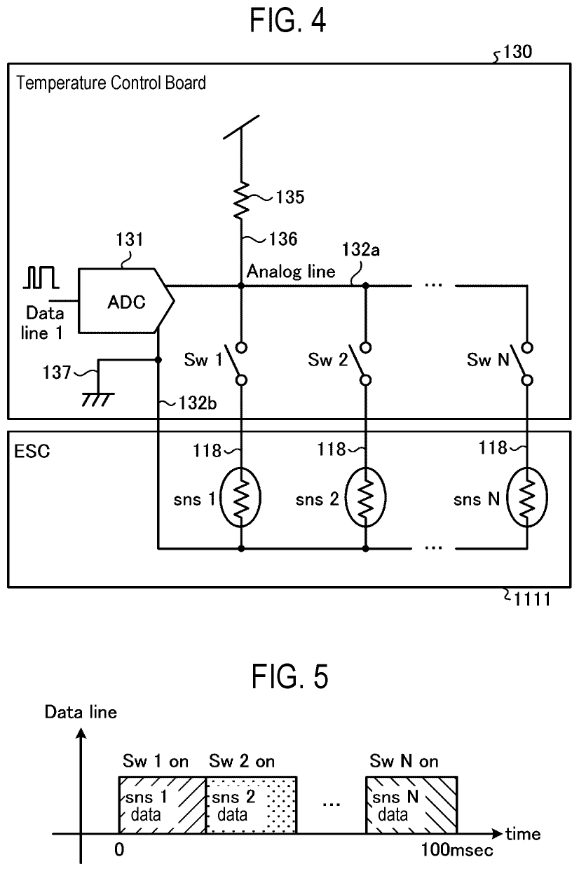

Therefore, in this embodiment, the substrate support 11 is configured as follows. FIG. 4 illustrates an example of the schematic configuration of the substrate support 11 according to the first embodiment. FIG. 4 illustrates a schematic circuit configuration of the electrostatic chuck 1111 and the temperature control board 130 constituting the substrate support 11 according to the first embodiment. As described above, the electrostatic chuck 1111 is provided with the temperature sensors sns for the zones 115. FIG. 4 illustrates temperature sensors sns1, sns2, . . . snsN provided in the electrostatic chuck 1111. In the example of FIG. 4, the temperature sensors sns are thermistors. A resistance value between terminals of the temperature sensor sns changes according to temperature. A connection line 118 is connected to each temperature sensor sns.

The temperature control board 130 is provided with an analog-to-digital converter (ADC) 131. A common line 132 (132a and 132b) is connected to the ADC 131.

Each connection line 118 is connected in parallel to the common lines 132a and 132b. Further, each connection line 118 is provided with a switch Sw. In FIG. 4, switches Sw1, Sw2, . . . . SwN are illustrated. The switch Sw corresponds to a first switch and a second switch of the present disclosure.

A wire 136, which is connected to a predetermined reference voltage system via a resistor 135, is connected to the common line 132a. A grounded wire 137 is connected to the common line 132b. The common line 132a corresponds to a signal line of the present disclosure. The common line 132b corresponds to a ground (GND) line of the present disclosure. The ADC 131 corresponds to a signal detector of the present disclosure.

The temperature control board 130 measures the temperature of each temperature sensor sns under the control of the controller 2. For example, the controller 2 individually turns on each switch Sw of each connection line 118 and controls the ADC 131 to measure a voltage level of the common line 132a during a turn-on period of the switch Sw. Then, based on the measured voltage level, the controller 2 performs control to calculate a resistance value of each temperature sensor sns and detect the temperature of each temperature sensor sns from the calculated resistance value.

When all the switches Sw are in a turn-off state, the voltage level of the common line 132a becomes a reference voltage. On the other hand, when any one of the switches Sw is in a turn-on state, the common line 132a is conductive with the temperature sensor sns via the connection line 118 with the switch Sw in the turn-on state. A resistance between terminals of the temperature sensor sns changes according to temperature. Therefore, the voltage level of the common line 132a changes according to the resistance value of the temperature sensor in the conductive state. The ADC 131 analog-to-digital (AD) converts the voltage of the common line 132a and outputs data representing a voltage value to the controller 2. The controller 2 stores conversion data indicating a relationship between the voltage value and the temperature. Based on the conversion data, the controller 2 converts the voltage value indicated by the data input from the ADC 131 into temperature data, thereby detecting the temperature of the temperature sensor sns in the connection line 118 with the switch Sw in the turn-on state.

The controller 2 detects the temperature of each temperature sensor sns by individually turning on the switches Sw of each connection line 118 and converting data input from the ADC 131 into temperature data during a turn-on period of each switch Sw. FIG. 5 illustrates an example of a flow of detecting the temperature of each temperature sensor sns according to the first embodiment. FIG. 5 illustrates an example of a period during which each switch Sw is sequentially turned on. The controller 2 individually and sequentially turns on the switches Sw1, Sw2, . . . , and SwN during a total of 100 ms. In FIG. 5, periods during which the switches Sw1, Sw2, . . . , and SwN are individually and sequentially turned on are indicated as Sw1 on, Sw2 on, . . . , and SwN on. The controller 2 detects the temperatures of the temperature sensors sns1, sns2, . . . , and snsN by converting the data input from the ADC 131 into temperature data during the turn-on periods of the switches Sw1, Sw2, . . . , and SwN. In FIG. 5, the temperature data of the temperature sensors sns1, sns2, . . . , and snsN are denoted as sns1 data, sns2 data, . . . , and snsN data.

The controller 2 controls power supplied from each heater control circuit 120 to each heater 116 so that the temperature of each zone 115 reaches a predetermined temperature according to the detected temperature of each temperature sensor sns.

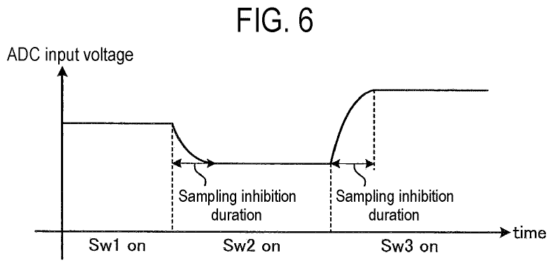

When the switches Sw are turned on sequentially, the voltage of the common line 132a changes to a voltage corresponding to the temperature of the temperature sensor sns in a conductive state. In this case, it takes a certain time for the voltage to stabilize. FIG. 6 illustrates an example of a fluctuation in the voltage of the common line 132a when switching the switches Sw according to the first embodiment. In FIG. 6, periods during which switches Sw1, Sw2, and Sw3 are sequentially turned on are denoted as Sw1 on, Sw2 on, and Sw3 on and the voltage fluctuation during the turn-on periods is illustrated. As illustrated in FIG. 6, when the switches Sw1, Sw2, and Sw3 are sequentially turned on, it takes a certain time until the voltage of the common line 132a becomes stable to a voltage corresponding to the temperature of the temperature sensor sns in a conductive state. When the ADC 131 AD-converts the voltage of the common line 132a during a transition time until the voltage stabilizes, correct temperature may not be detected.

Therefore, when the switches Sw are sequentially turned on, the controller 2 performs control to measure the temperature during each turn-on period after a predetermined sampling inhibition time period has elapsed from the start of the turn-on period. For example, the controller 2 controls the ADC 131 to AD-convert the voltage of the common line 132a during each turn-on period after the sampling inhibition time period has elapsed from the start of the turn-on period. The sampling inhibition time period is set to be longer than the transition time until the voltage stabilizes. For example, the sampling inhibition time period is set to the transition time. The transition time is determined according to a time constant of a resistance R and a capacitor C of a circuit in a conductive state when the switch Sw is turned on. The sampling inhibition time period is determined according to the time constant of the resistance R and the capacitor C of a circuit including the common lines 132a and 132b, the connection lines 118 and the like, which are in a conductive state when the switch Sw is turned on.

Further, noise may occur during the AD-conversion performed by the ADC 131.

Therefore, the controller 2 controls the ADC 131 to AD-convert the voltage of the common line 132a multiple times during each turn-on period. For example, the controller 2 controls the ADC 131 to AD-convert the voltage of the common line 132a one hundred times during each turn-on period after the sampling inhibition time period has elapsed from the start of the turn-on period. The controller 2 averages plural rounds of data input from the ADC 131 to detect the temperature.

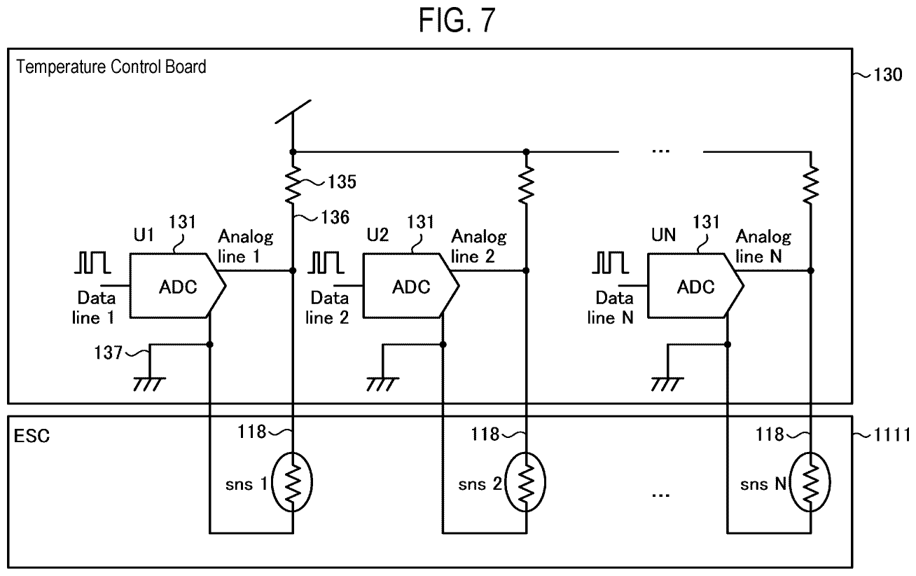

Next, an example of a configuration of a substrate support 11 in the related art will be described as Comparative Example. FIG. 7 illustrates an example of the configuration of the substrate support 11 according to Comparative Example. In FIG. 7, a schematic circuit configuration of the electrostatic chuck 1111 and the temperature control board 130 which constitute the substrate support 11 according to Comparative Example is illustrated. The temperature control board 130 of Comparative Example is provided with an ADC 131 corresponding to each temperature sensor sns. The temperature sensors sns are individually connected to the ADC 131 via respective connection lines 118. The temperature control board 130 of Comparative Example may measure the temperature of each temperature sensor sns in a parallel manner by AD-converting the voltage of each connection line 118 by each ADC 131.

However, in the configuration as illustrated in FIG. 7, the temperature control board 130 according to Comparative Example requires as many ADCs 131 as the number of temperature sensors sns. For example, in a case where the number of zones 115 of the substrate support 11 is N and N temperature sensors are provided, the temperature control board 130 of Comparative Example requires N ADCs 131. Further, the temperature control board 130 of Comparative Example requires two connectors for connection to each temperature sensor. This increases the number of connectors. For example, when N temperature sensors sns are provided in Comparative Example, the temperature control board 130 requires 2N connectors.

On the other hand, the temperature control board 130 according to the first embodiment connects each connection line 118 in parallel to the common lines 132a and 132b and individually turns on the switches Sw to measure the temperature of each temperature sensor sns in a time division manner. Thus, the temperature control board 130 according to the first embodiment may reduce the number of ADCs 131. For example, the temperature control board 130 according to the first embodiment may measure the temperature of each temperature sensor sns using a single ADC 131. Further, the temperature control board 130 according to the first embodiment may reduce the number of connectors required for connection to each temperature sensor sns compared to Comparative Example. For example, in this embodiment, the number of connectors required for connection to each temperature sensor sns may be reduced to N+1.

As described above, according to the present embodiment, the increase in the number of components used for temperature measurement may be suppressed.

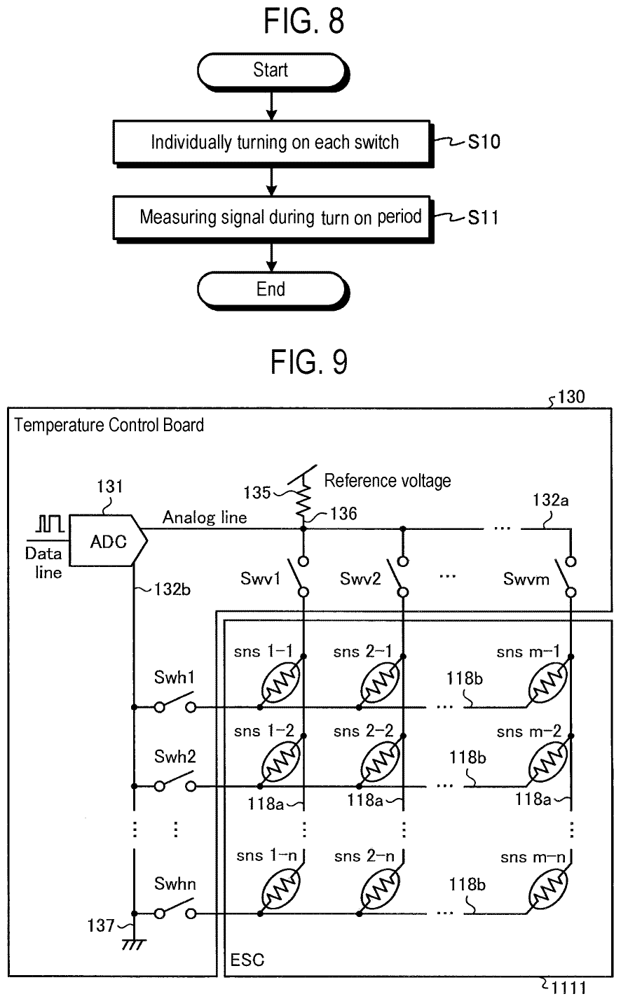

Next, a processing flow of a temperature measurement method performed by the plasma processing apparatus 1 according to an embodiment will be described. FIG. 8 illustrates an example of a processing procedure of the temperature measurement method according to the first embodiment. The processing of the temperature measurement method illustrated in FIG. 8 is executed when measuring the temperature of each zone 115.

The controller 2 controls each switch Sw of each connection line 118 to be individually turned on (Step S10).

The controller 2 controls the ADC 131 to measure a signal during a turn-on period of each switch Sw (Step S11). For example, the controller 2 controls the ADC 131 to AD-convert the voltage of the common line 132a during each turn-on period after the sampling inhibition time period has elapsed from the start of the turn-on period. The controller 2 converts data input from the ADC 131 into temperature data during the turn-on period of each switch Sw to detect the temperature of each temperature sensor sns, and the processing ends.

As described above, the plasma processing apparatus 1 according to the first embodiment includes the plasma processing chamber 10, the base 1110, the electrostatic chuck 1111, the first heater electrode layer (the heater 116), the second heater electrode layer (the heater 116), the first temperature sensor (the temperature sensor sns), the second temperature sensor (the temperature sensor sns), the signal line (the common line 132a), the GND line (the common line 132b), and the signal detector (the ADC 131). The base 1110 is disposed in the plasma processing chamber 10. The electrostatic chuck 1111 is disposed on the base 1110. The first heater electrode layer is disposed in the electrostatic chuck 1111. The second heater electrode layer is disposed in the electrostatic chuck 1111 at a position different from the first heater electrode layer in a plan view. The first temperature sensor measures the temperature of the first heater electrode layer. The second temperature sensor measures the temperature of the second heater electrode layer. The signal line is electrically connected to the first temperature sensor and the second temperature sensor. The GND line is electrically connected to the first temperature sensor and the second temperature sensor. The signal detector is electrically connected to the signal line and the GND line. With the plasma processing apparatus 1 configured as above, the number of connectors required for connection to the signal detector and the temperature sensors may be reduced. This makes it possible to suppress the increase in the number of components used for temperature measurement.

Further, the plasma processing apparatus 1 according to the first embodiment further includes the controller 2. The controller 2 executes processing including an operation of measuring the temperature of the first heater electrode layer using the first temperature sensor during a first period, and an operation of measuring the temperature of the second heater electrode layer using the second temperature sensor during a second period after the first period. With the plasma processing apparatus 1 configured as above, it is possible to measure the temperatures of the first temperature sensor and the second temperature sensor in a time division manner.

In addition, the plasma processing apparatus 1 according to the first embodiment further includes the first switch (the switch Sw) and the second switch (the switch Sw). The first switch is disposed between the signal line and the first temperature sensor. The second switch is disposed between the signal line and the second temperature sensor. The controller 2 executes processing including an operation of measuring the temperature of the first heater electrode layer using the first temperature sensor by turning on the first switch during the first period, and an operation of measuring the temperature of the second heater electrode layer using the second temperature sensor by turning on the second switch during the second period. Further, the controller 2 turns off the second switch during the first period and turns off the first switch during the second period. With the plasma processing apparatus 1 configured as above, it is possible to measure the temperatures of the first temperature sensor and the second temperature sensor in a time division manner by controlling the first switch and the second switch.

The controller 2 sets a non-measurement period (the sampling inhibition time period) between the first period and the second period. This prevents the plasma processing apparatus 1 from measuring temperature during the voltage transition when switching the switches Sw, which makes it possible to accurately detect the temperature.

The first temperature sensor and the second temperature sensor are disposed in the base 1110, in the electrostatic chuck 1111, or in the bonding layer 1112 that bonds the base 1110 and the electrostatic chuck 1111 to each other. Thus, the plasma processing apparatus 1 may measure the temperature of the first heater electrode layer or the second heater electrode layer using the base 1110, the electrostatic chuck 1111, or the bonding layer 1112.

Further, the signal detector is an ADC. Thus, a signal corresponding to a temperature output from the temperature sensors may be converted into digital data.

### Second Embodiment

Next, a second embodiment will be described. A plasma processing system, a plasma processing apparatus 1, and a controller 2 according to the second embodiment have the same configurations as those in the first embodiment, and therefore, descriptions of the same parts will be omitted and differences between the first embodiment and the second embodiment will be mainly described.

FIG. 9 illustrates an example of a schematic configuration of the substrate support 11 according to the second embodiment. FIG. 9 illustrates a schematic circuit configuration of the electrostatic chuck 1111 and the temperature control board 130 which constitute the substrate support 11 according to the second embodiment. The electrostatic chuck 1111 is provided with a temperature sensor sns for each zone 115. In FIG. 9, temperature sensors sns1-1, sns1-2, . . . , and snsm-n provided in the electrostatic chuck 1111 are illustrated. In the example of FIG. 9, the temperature sensor sns is a thermistor.

The substrate support 11 according to the second embodiment includes a plurality of first connection lines 118a and a plurality of second connection lines 118b. One of two terminals of the temperature sensor sns is connected to one of the plurality of first connection lines 118a, and the other of the two terminals thereof is connected to one of the plurality of second connection lines 118b. FIG. 9 illustrates a configuration in which the temperature sensors sns are arranged in a grid shape but the temperature sensors sns arranged in each zone 115 may be connected in the grid shape in a circuit as illustrated in FIG. 2. Further, the temperature sensors sns may be arranged and connected in the grid shape. For example, the placement surface 114 of the substrate support 11 may be divided into the zones 115 in the grid shape. The heaters 116 and the temperature sensors sns are arranged in the substrate support 11 and are connected to each other in the grid shape.

The temperature control board 130 is provided with the ADC 131. The common line 132 (132a and 132b) is connected to the ADC 131. The wire 136 connected to a predetermined reference voltage system via the resistor 135 is connected to the common line 132a. The grounded wire 137 is connected to the common line 132b. The common line 132a corresponds to the signal line of the present disclosure. The common line 132b corresponds to the GND line of the present disclosure. The ADC 131 corresponds to the signal detector of the present disclosure.

Each first connection line 118a is connected in parallel to the common line 132a. Each second connection line 118b is connected in parallel to the common line 132b. Each first connection line 118a is provided with the first switch Swv. Each second connection line 118b is provided with the second switch Swh. FIG. 9 illustrates first switches Swv1, Swv2, . . . , and Swvm provided in the first connection lines 118a and the second switches Swh1, Swh2, . . . , and Swhn provided in the second connection lines 118b. The first switch Swv corresponds to a first switch and a second switch of the present disclosure. The second switch Swh corresponds to a third switch and a fourth switch of the present disclosure.

The temperature control board 130 measures the temperature of each temperature sensor sns under the control of the controller 2. For example, the controller 2 individually turns on the plurality of first switches Swv and the plurality of second switches Swh. For example, the controller 2 performs control to sequentially turn on one sides of the plurality of first switches Swv and the plurality of second switches Swh and to sequentially turn on the other sides of the first switches Swv and the second switches Swh during turn-on periods of the one sides of the first switches Swv and the second switches Swh. When the first switch Swv and the second switch Swh are turned on, the temperature sensor sns connected to the first connection line 118a of the first switch Swv in a turn-on state and the second connection line 118b of the second switch Swh in a turn-on state is conductive with the common lines 132a and 132b. A resistance between terminals of the temperature sensor sns changes according to temperature. Therefore, the voltage level of the common line 132a changes according to the resistance value of the temperature sensor sns in a conductive state. The ADC 131 AD-converts the voltage of the common line 132a and outputs data indicating the voltage value to the controller 2.

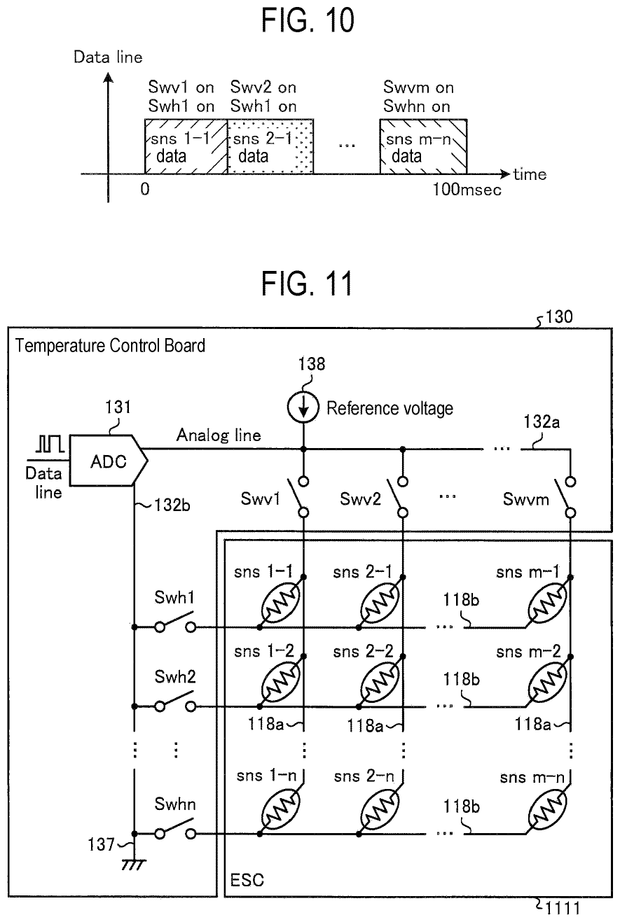

The controller 2 individually turns on the plurality of first switches Swv and the plurality of second switches Swh, and converts the data input from the ADC 131 into temperature data during the turn-on period of the first switch Swv and the second switch Swh, thereby detecting the temperature of each temperature sensor sns. FIG. 10 illustrates an example of a flow of detecting the temperature of each temperature sensor sns according to the second embodiment. FIG. 10 illustrates an example of a period during which the switches Sw are sequentially turned on. For example, the controller 2 sequentially turns on the second switches Swh in a total of 100 ms and sequentially turns on the first switches Swv during the turn-on period of the second switches Swh. In FIG. 10, the second switch Swh1 is turned on, the first switch Swv1 is turned on, and subsequently, the first switch Swv2 is turned on while the second switch Swh1 is turned on. In FIG. 10, periods during which both the first switch Swv1 and the second switch Swh1 are turned on are indicated as “Swv1 on” and “Swh1 on.” In addition, periods during which both the first switch Swv2 and the second switch Swh1 are turned on are indicated as “Swv2 on” and “Swh1 on.” Periods during which both the first switch Swvm and the second switch Swhn are turned on are indicated as “Swvm on” and “Swhn on.”

As such, in the temperature control board 130 according to the second embodiment, each first connection line 118a is connected in parallel to the common line 132a, and each second connection line 118b is connected in parallel to the common line 132b. The temperature control board 130 according to the second embodiment individually turns on the first switch Swv and the second switch Swh, and measures the temperature of each temperature sensor sns in a time division manner during the turn-on periods of the first switch Swv and the second switch Swh. Thus, the temperature control board 130 according to the second embodiment may reduce the number of ADCs 131. For example, the temperature control board 130 according to the second embodiment may measure the temperature of each temperature sensor sns using a single ADC 131. Further, the temperature control board 130 according to the second embodiment may reduce the number of connectors required for connection to each temperature sensor sns compared to Comparative Example. For example, the temperature control board 130 according to the second embodiment may reduce the number of connectors required for connection to each temperature sensor sns by (N)^{1/2}+1.

As described above, according to the present embodiment, it is possible to suppress the increase in the number of components used for temperature measurement.

As described above, the plasma processing apparatus 1 according to the second embodiment further includes the third switch (the second switch Swh) and the fourth switch (the second switch Swh). The third switch is disposed between the GND line and the first temperature sensor. The fourth switch is disposed between the GND line and the second temperature sensor. The controller 2 executes processing including an operation of measuring the temperature of the first heater electrode layer using the first temperature sensor by turning on the first switch (for example, the first switch Swv1) and the third switch (for example, the second switch Swh1) during the first period, and an operation of measuring the temperature of the second heater electrode layer using the second temperature sensor by turning on the second switch (for example, the first switch Swv2) and the fourth switch (for example, the second switch Swh2) during the second period. Thus, according to the plasma processing apparatus 1, the number of connectors required for connection to the signal detector and the temperature sensor may be further reduced. This suppresses an increase in the number of components.

Further, the controller 2 turns off the second switch (for example, the first switch Swv2) and the fourth switch (for example, the second switch Swh2) during the first period and turns off the first switch (for example, the first switch Swv1) and the third switch (for example, the second switch Swh1) during the second period. Thus, the plasma processing apparatus 1 may measure the temperatures of the first temperature sensor, the second temperature sensor, and the third temperature sensor in a time division manner by controlling the first switch to the fourth switch.

The plasma processing apparatus 1 according to the second embodiment includes the third heater electrode layer (the heater 116) and the third temperature sensor (the temperature sensor sns). The third heater electrode layer is disposed in a grid shape together with the first heater electrode layer and the second heater electrode layer in a plan view. The third temperature sensor is disposed in the grid shape together with the first temperature sensor and the second temperature sensor in a plan view, and measures the temperature of the third heater electrode layer. The third temperature sensor is electrically connected to the signal line and the GND line. The controller 2 executes processing further including an operation of measuring the temperature of the third heater electrode layer using the third temperature sensor during a third period different from the first period and the second period. Thus, the plasma processing apparatus 1 may measure the temperatures of the first temperature sensor, the second temperature sensor, and the third temperature sensor in a time division manner.

It should be noted that the embodiments disclosed herein are exemplary in all aspects and are not restrictive. Indeed, the above-described embodiments may be implemented in various forms. The above-described embodiments may be omitted, replaced, or modified in various forms without departing from the scope and spirit of the appended claims.

For example, in the above embodiments, a case in which the plasma processing is performed on a semiconductor wafer as the substrate W has been described as an example, but the present disclosure is not limited thereto. Any type of substrate may be used as the substrate W.

Further, in the above embodiments, the plasma processing system for performing plasma etching has been described as an example, but the present disclosure is not limited thereto. The plasma processing apparatus may be any apparatus that performs plasma processing on the substrate W with temperature sensors sns provided for the zones of the placement surface of the stage on which the substrate W is placed. For example, the plasma processing apparatus may be a film formation apparatus which generates plasma to form a film.

In the above embodiment, a case in which the temperature control board 130 connects the wire 136 connected to the predetermined reference voltage to the common line 132a via the resistor 135, and the ADC 131 detects the voltage based on the reference voltage, has been described as an example. However, the present disclosure is not limited thereto. The temperature control board 130 may connect a constant current circuit to the common line 132a, and the ADC 131 may detect a voltage based on a voltage of the constant current circuit. FIG. 11 illustrates another example of a schematic configuration of the substrate support 11 according to the second embodiment. In the temperature control board 130 of FIG. 11, a constant current circuit 138 is connected to the common line 132a. The ADC 131 detects a voltage changed by a temperature sensor sns1 based on a voltage of the constant current circuit 138.

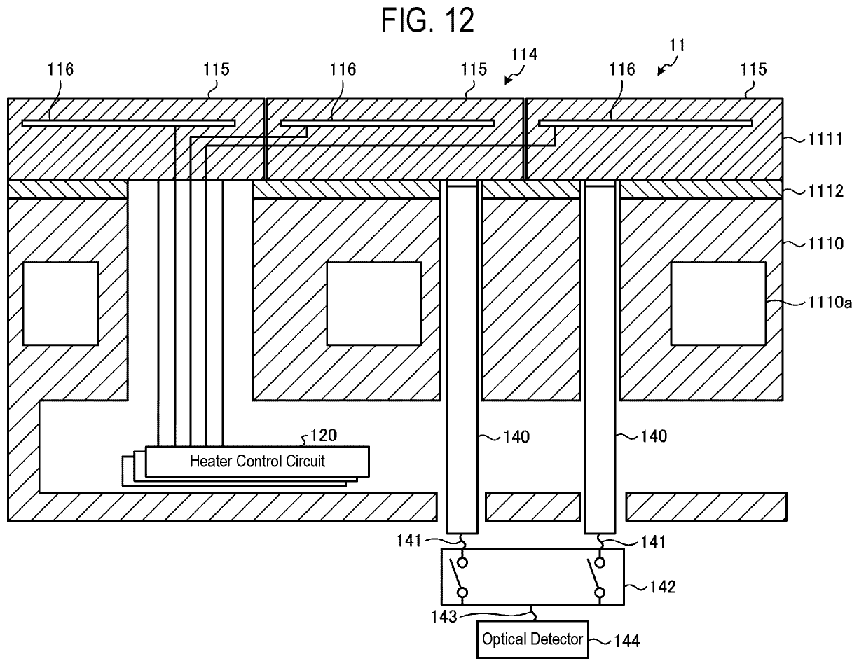

In the above embodiment, a case in which the temperature sensor sns is a thermistor, and the ADC 131 detects the voltage changed by the temperature sensor sns has been described as an example. However, the present disclosure is not limited thereto. The temperature sensor sns may be an optical temperature sensor. FIG. 12 illustrates an example of a configuration of the substrate support 11 according to another embodiment. The base 1110 is provided with each optical waveguide 140 for each zone 115. Each optical waveguide 140 is connected to one end of an optical fiber 141. The other end of the optical fiber 141 is connected to a zone selection switch 142. The zone selection switch 142 is connected to an optical detector 144 via an optical fiber 143. The optical detector 144 irradiates light of various interference waves and detects a signal intensity of reflected light. A refractive index of the optical waveguide 140 changes according to temperature. Therefore, before and after the temperature changes, positions of interference waveforms shift due to a change in an optical path length of the optical waveguide 140, and a width between peaks of the interference waveform changes. The controller 2 detects a temperature by sequentially switching the optical waveguides 140 using the zone selection switch 142 and measuring the peaks of the interference waveforms in each optical waveguide 140 using the optical detector 144. The substrate support 11 illustrated in FIG. 12 measures a temperature in each optical waveguide 140 in a time division manner using the zone selection switch 142. Thus, according to the temperature control board 130 illustrated in FIG. 12, the number of optical detectors 144 may be reduced.

According to the present disclosure, it is possible to suppress an increase in the number of components used for temperature measurement.

It should be noted that the embodiments disclosed herein are exemplary in all aspects and are not restrictive. Indeed, the above-described embodiments may be implemented in various forms. The above-described embodiments may be omitted, replaced, or modified in various forms without departing from the scope and spirit of the appended claims.

The above embodiments are described as supplementary notes below.

### (Supplementary Note 1)

A plasma processing apparatus is provided including:
a plasma processing chamber;
a base disposed in the plasma processing chamber;
an electrostatic chuck disposed on the base;
a first heater electrode layer disposed in the electrostatic chuck;
a second heater electrode layer disposed in the electrostatic chuck at a position different from the first heater electrode layer in a plan view;
a first temperature sensor configured to measure a temperature of the first heater electrode layer;
a second temperature sensor configured to measure a temperature of the second heater electrode layer;
a signal line electrically connected to the first temperature sensor and the second temperature sensor;
a ground (GND) line electrically connected to the first temperature sensor and the second temperature sensor; and
a signal detector electrically connected to the signal line and the GND line.

### (Supplementary Note 2)

In the plasma processing apparatus of Supplementary Note 1, the plasma processing apparatus further includes a controller configured to execute process including measuring the temperature of the first heater electrode layer using a first temperature sensor during a first period and measuring the temperature of the second heater electrode layer using the second temperature sensor during a second period after the first period.

### (Supplementary Note 3)

In the plasma processing apparatus of Supplementary Note 2, the plasma processing apparatus further includes:
a first switch disposed between the signal line and the first temperature sensor; and
a second switch disposed between the signal line and the second temperature sensor,
wherein the controller executes the process including:
measuring the temperature of the first heater electrode layer using the first temperature sensor by turning on the first switch during the first period; and
measuring the temperature of the second heater electrode layer using the second temperature sensor by turning on the second switch during the second period.

### (Supplementary Note 4)

In the plasma processing apparatus of Supplementary Note 3, the controller turns off the second switch during the first period and turns off the first switch during the second period.

### (Supplementary Note 5)

In the plasma processing apparatus of Supplementary Note 3 or 4, the plasma processing apparatus further includes:
a third switch disposed between the GND line and the first temperature sensor; and
a fourth switch disposed between the GND line and the second temperature sensor,
wherein the controller executes the process including:
measuring the temperature of the first heater electrode layer using the first temperature sensor by turning on the first switch and the third switch during the first period, and
measuring the temperature of the second heater electrode layer using the second temperature sensor by turning on the second switch and the fourth switch during the second period.

### (Supplementary Note 6)

In the plasma processing apparatus of Supplementary Note 5, the controller turns off the second switch and the fourth switch during the first period and turns off the first switch and the third switch during the second period.

### (Supplementary Note 7)

In the plasma processing apparatus of any one of Supplementary Notes 2 to 6, the plasma processing apparatus further includes:
a third heater electrode layer disposed in a grid shape along with the first heater electrode layer and the second heater electrode layer in a plan view; and
a third temperature sensor disposed in the grid shape along with the first temperature sensor and the second temperature sensor in a plan view and configured to measure a temperature of the third heater electrode layer,
wherein the third temperature sensor is electrically connected to the signal line and the GND line, and
wherein the controller executes the process further including measuring the temperature of the third heater electrode layer using the third temperature sensor during a third period different from the first period and the second period.

### (Supplementary Note 8)

In the plasma processing apparatus of any one of Supplementary Notes 2 to 7, the controller is configured to provide a non-measurement period between the first period and the second period.

### (Supplementary Note 9)

In the plasma processing apparatus of any one of Supplementary Notes 1 to 8, the first temperature sensor and the second temperature sensor are disposed in the base, in the electrostatic chuck, or in a bonding layer bonding the base and the electrostatic chuck to each other.

### (Supplementary Note 10)

In the plasma processing apparatus of any one of Supplementary Notes 1 to 9, the signal detector is an analog-to-digital converter.

### (Supplementary Note 11)

In a temperature measurement method of a plasma processing apparatus, the plasma processing apparatus includes:
a plasma processing chamber;
a base disposed in the plasma processing chamber;
an electrostatic chuck disposed on the base;
a first heater electrode layer disposed in the electrostatic chuck;
a second heater electrode layer disposed in the electrostatic chuck at a position different from the first heater electrode layer in a plan view;
a first temperature sensor configured to measure a temperature of the first heater electrode layer;
a second temperature sensor configured to measure a temperature of the second heater electrode layer;
a signal line electrically connected to the first temperature sensor and the second temperature sensor;
a ground (GND) line electrically connected to the first temperature sensor and the second temperature sensor; and
a signal detector electrically connected to the signal line and the GND line, and
the temperature measurement method includes:
measuring a temperature of the first heater electrode layer using the first temperature sensor during a first period; and
measuring a temperature of the second heater electrode layer using the second temperature sensor during a second period after the first period.

What is claimed is:

1. A plasma processing apparatus, comprising:
a plasma processing chamber;
a base disposed in the plasma processing chamber;
an electrostatic chuck disposed on the base;
a first heater electrode layer disposed in the electrostatic chuck;
a second heater electrode layer disposed in the electrostatic chuck at a position different from the first heater electrode layer in a plan view;
a first temperature sensor configured to measure a temperature of the first heater electrode layer;
a second temperature sensor configured to measure a temperature of the second heater electrode layer;
a signal line electrically connected to the first temperature sensor and the second temperature sensor;
a ground (GND) line electrically connected to the first temperature sensor and the second temperature sensor; and
a signal detector electrically connected to the signal line and the GND line.

2. The plasma processing apparatus of claim 1, further comprising:
a controller configured to execute a process including measuring the temperature of the first heater electrode layer using the first temperature sensor during a first period and measuring the temperature of the second heater electrode layer using the second temperature sensor during a second period after the first period.

3. The plasma processing apparatus of claim 2, further comprising:
a first switch disposed between the signal line and the first temperature sensor; and
a second switch disposed between the signal line and the second temperature sensor,
wherein the controller is configured to execute a process including measuring the temperature of the first heater electrode layer using the first temperature sensor by turning on the first switch during the first period, and measuring the temperature of the second heater electrode layer using the second temperature sensor by turning on the second switch during the second period.

4. The plasma processing apparatus of claim 3, wherein the controller turns off the second switch during the first period and turns off the first switch during the second period.

5. The plasma processing apparatus of claim 3, further comprising:
a third switch disposed between the GND line and the first temperature sensor; and
a fourth switch disposed between the GND line and the second temperature sensor,
wherein the controller is configured to execute a process including measuring the temperature of the first heater electrode layer using the first temperature sensor by turning on the first switch and the third switch during the first period, and measuring the temperature of the second heater electrode layer using the second temperature sensor by turning on the second switch and the fourth switch during the second period.

6. The plasma processing apparatus of claim 5, wherein the controller turns off the second switch and the fourth switch during the first period and turns off the first switch and the third switch during the second period.

7. The plasma processing apparatus of claim 2, further comprising:
a third heater electrode layer disposed in a grid shape along with the first heater electrode layer and the second heater electrode layer in a plan view; and
a third temperature sensor disposed in the grid shape along with the first temperature sensor and the second temperature sensor in a plan view and configured to measure a temperature of the third heater electrode layer,
wherein the third temperature sensor is electrically connected to the signal line and the GND line, and
wherein the controller is configured to execute the process further including measuring the temperature of the third heater electrode layer using the third temperature sensor during a third period different from the first period and the second period.

8. The plasma processing apparatus of claim 2, wherein the controller is configured to set a non-measurement period between the first period and the second period.

9. The plasma processing apparatus of claim 1, wherein the first temperature sensor and the second temperature sensor are disposed in the base, in the electrostatic chuck, or in a bonding layer configured to bond the base and the electrostatic chuck to each other.

10. The plasma processing apparatus of claim 1, wherein the signal detector is an analog-to-digital converter.

11. A temperature measurement method used in a plasma processing apparatus,
wherein the plasma processing apparatus includes:
a plasma processing chamber;
a base disposed in the plasma processing chamber;
an electrostatic chuck disposed on the base;
a first heater electrode layer disposed in the electrostatic chuck;
a second heater electrode layer disposed in the electrostatic chuck at a position different from the first heater electrode layer in a plan view;
a first temperature sensor configured to measure a temperature of the first heater electrode layer;
a second temperature sensor configured to measure a temperature of the second heater electrode layer;
a signal line electrically connected to the first temperature sensor and the second temperature sensor;
a ground (GND) line electrically connected to the first temperature sensor and the second temperature sensor; and
a signal detector electrically connected to the signal line and the GND line, and
wherein the temperature measurement method comprises:
measuring the temperature of the first heater electrode layer using the first temperature sensor during a first period; and
measuring the temperature of the second heater electrode layer using the second temperature sensor during a second period after the first period.
